(19) United States
(12) Patent Application Publication
(10) Pub. No.: US 2006/0180923 A1
(43) Pub. Date: Aug. 17, 2006

(54) Heat sink

(75) Inventor: Yen-Hsun Chou, Taoyuan County (TW)

Correspondence Address: BROWDY AND NEIMARK, P.L.L.C.;624 NINTH STREET, NW, SUITE 300, WASHINGTON, DC, 20001-5303, US

(73) Assignee: Yuh-Cheng Chemical Ltd., Taipei City (TW)

(21) Appl. No.: 11/058,318

(22) Filed: Feb. 16, 2005

(51) Int. Cl. H01L 23/34

(52) U.S. Cl. 257/706

(57) ABSTRACT

A heat sink includes a plurality of plate members combined together. Each plate member has a flat rectangular body provided with mounting holes, two sidewalls extending from a first side and a second side of the flat rectangular body, and a plurality of mounting lugs respectively provided at bottom side of the sidewalls in such a manner that the mounting lugs of one plate member are insertable into the mounting holes of another plate member. Each mounting lug is provided with a retaining spring strip for stopping against a bottom side of the flat rectangular body of another plate member upon insertion with the respective mounting lugs of one plate member into the mounting holes of another plate member.

### BACKGROUND OF THE INVENTION

1. Field of the Invention

The present invention relates to a heat sink for dissipating heat from a heat source and more particularly, to a heat sink, which is easy to assemble and is stable in structure.

2. Description of the Related Art

A conventional heat sink 1, as shown in FIG. 1, is formed of a plurality of plate members 2 connected in a stack. Each plate member 2 has a plurality of mounting lugs 3 and a plurality of mounting through holes 4 corresponding to the mounting lugs 3. Each mounting lug 3 has a base 5 and two upright arms 6 at two sides of the base 5. During installation, the plate members 2 are fastened together by: inserting the mounting lugs 3 of one plate member 2 into the mounting through holes 4 of another plate member 2 and then hammering down the upright arms 6 of each mounting lug 3. This structure of heat sink 1 is basically stable, however its complicated installation procedure requires much time and labor, resulting in a high manufacturing cost.

### SUMMARY OF THE INVENTION

The present invention has been accomplished under the circumstances in view. It is the main object of the present invention to provide a heat sink, which is easy to assemble and is stable in its structure.

To achieve this object of the present invention, the heat sink provided by the present invention comprises a plurality of plate members combined together. Each plate member has a flat rectangular body having at least one mounting hole, a first sidewall extending from a first side of the flat rectangular body and provided with at least one mounting lug for inserting into the mounting hole of another plate member, and a second sidewall extending from a second side of the flat rectangular body. Each mounting lug of the plate member has an upwardly obliquely extending retaining spring strip which is stopped against a bottom side of the flat rectangular body of another plate member upon insertion of the mounting lug of one plate member into the mounting hole of another plate member.

### BRIEF DESCRIPTION OF THE DRAWINGS

FIG. 1 is a perspective view of a heat sink according to the prior art.

FIG. 2 is an exploded view of a heat sink according to a preferred embodiment of the present invention.

FIG. 3 is a front view of a part of one plate member for heat sink according to the preferred embodiment of the present invention.

FIG. 4 is an exploded view in section of a part of the heat sink according to the preferred embodiment of the present invention.

FIG. 5 is a sectional assembly view of FIG. 4.

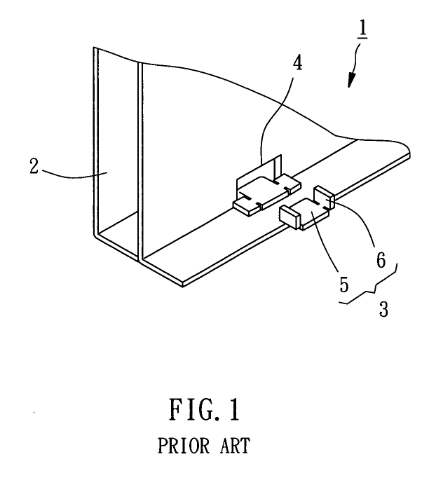

### DETAILED DESCRIPTION OF THE INVENTION

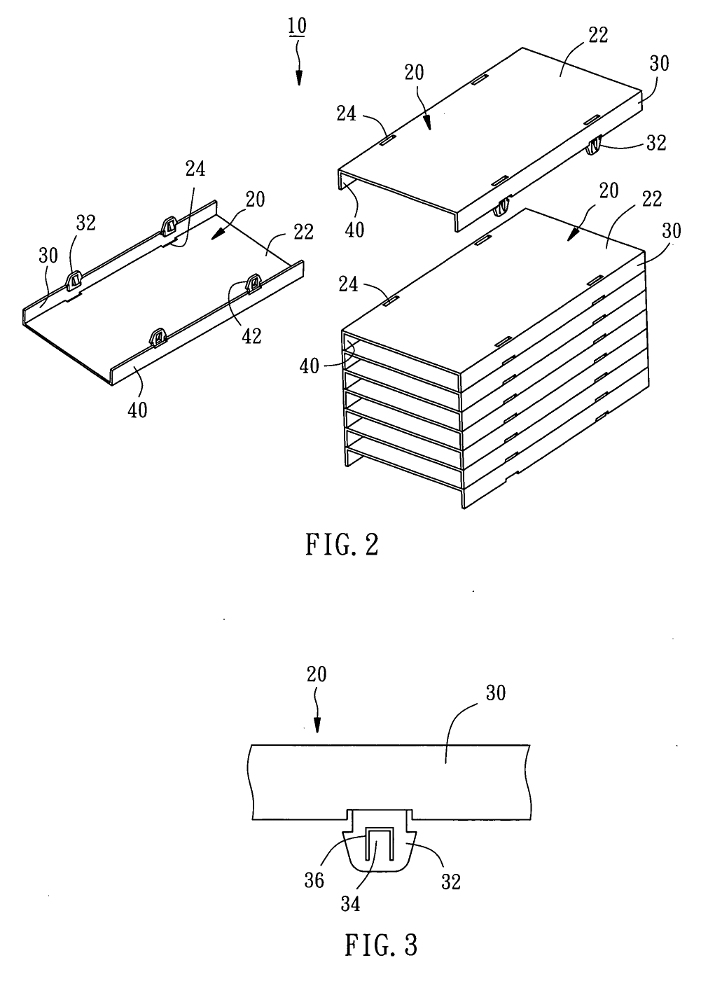

Referring to FIGS. 2 and 3, a heat sink 10 in accordance with the preferred embodiment of the present invention is shown comprised of a plurality of plate members 20 connected in a stack. Each plate member 20 comprises a flat rectangular body 22, a first sidewall 30 perpendicularly integrally extending from one lateral side of the body 22, and a second sidewall 40 perpendicularly integrally extending from the other lateral side of the body 22. The plate members 20 are made from heat conducting material, for example, copper or aluminum. The flat rectangular body 22 of the plate member 20 has four mounting holes 24 symmetrically disposed at two sides adjacent to the first sidewall 30 and the second sidewall 40.

The first sidewall 30 has two trapezoidal mounting lugs 32 for inserting two mounting holes 24 in the flat rectangular body 22 of a second plate member 20. Each trapezoidal mounting lug 32 has an obliquely upwardly extending retaining spring strip 34 for stopping against the bottom wall of the rectangular body 22 of the said second plate member 20 after insertion of the respective trapezoidal mounting lug 32 into the respective mounting hole 24 in the flat rectangular body 22 of the said second plate member 20. The retaining spring strip 34 may be integrally formed of a part of the trapezoidal mounting lug 32 by making an U-shaped through slot 36 in the trapezoidal mounting lug 32 and then bending the portion that is surrounded by the U-shaped through slot 36.

Similar to the structure of the first sidewall 30, the second sidewall 40 has two trapezoidal mounting lugs 42, and each of the trapezoidal mounting lugs 42 has an obliquely upwardly extending retaining spring strip 44.

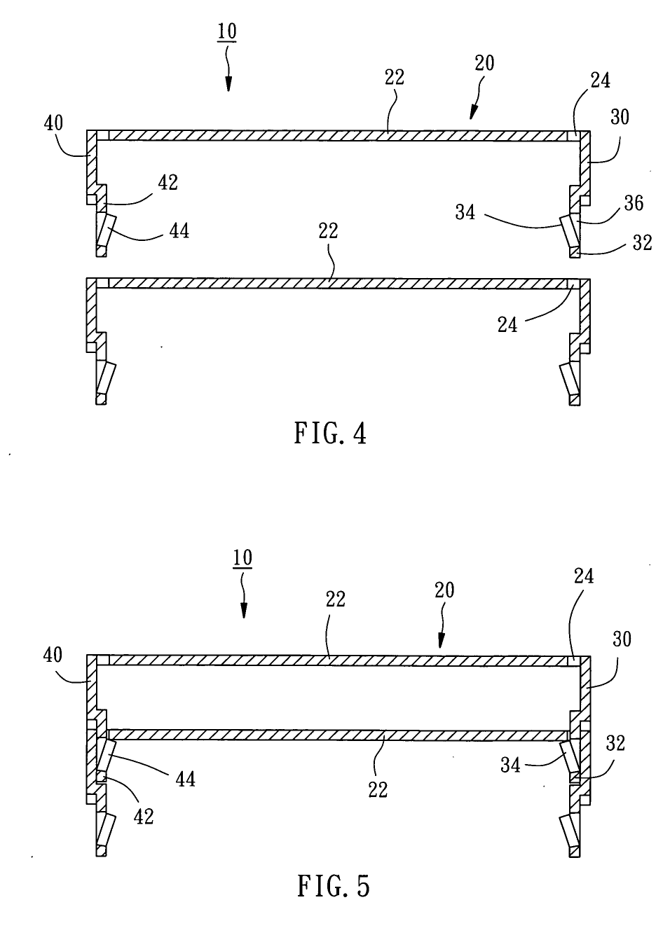

Referring to FIG. 4, when attaching one plate member 20 to another to assemble the desired heat sink 10, the trapezoidal mounting lugs 32, 42 of one plate member 20 are respectively inserted into the mounting holes 24 of another, keeping the retaining spring strips 34, 44 of the trapezoidal mounting lugs 32, 42 of one plate member 20 stopped at the bottom side of the flat rectangular body 22 of another plate member 20.

Therefore, the prepared plate members 20 can easily and quickly be assembled to form the desired heat sink 10 simply by inserting the respective trapezoidal mounting lugs 32, 42 of one plate member 20 into the respective mounting holes 24 of another plate member 20.

The present invention may be variously embodied. In the aforesaid embodiment, the first sidewall and the second sidewall are provided at two opposite lateral sides of the flat rectangular body. Alternatively, the first sidewall and the second sidewall can be provided at two adjacent sides of the flat rectangular body. Further, the trapezoidal mounting lugs, the mounting holes, or the retaining spring strips may be variously shaped. The number or locations of the trapezoidal mounting lugs may be changed to fit different requirements.

1. A heat sink comprising:
a plurality of plate members combined together;
wherein each of said plate members has a flat rectangular body having at least one mounting hole, a first sidewall extending from a first side of said flat rectangular body and provided with at least one mounting lug for inserting into the mounting hole of another said plate members, and a second sidewall extending from a second side of said flat rectangular body;
wherein said at least one mounting lug of said plate members has an upwardly obliquely extending resilient retaining tongue, an end thereof abutting against a bottom side of the flat rectangular body of said another said plate members.

2. The heat sink as claimed in claim 1, wherein each said mounting lug has a U-shaped through slot surrounding the respective resilient retaining tongue.
